(19) United States
(12) Patent Application Publication
(10) Pub. No.: US 2007/0079751 A1
(43) Pub. Date: Apr. 12, 2007

(54) Inp single crystal, gaas single crystal, and method for production thereof

(76) Inventor: Fumio Matsumoto, Saitama (JP)

Correspondence Address: SUGHRUE MION, PLLC, 2100 PENNSYLVANIA AVENUE, N.W., SUITE 800, WASHINGTON, DC, 20037, US

(21) Appl. No.: 10/564,734

(22) PCT Filed: Jul. 16, 2004
(86) PCT No.: PCT/JP04/01055

§ 371 Date: Jun. 29, 2006

(30) Foreign Application Priority Data
Jul. 17, 2003 (JP) 2003-275987

(51) Int. Cl. C30B 23/00; C30B 25/00; C30B 28/12; C30B 28/14

(52) U.S. Cl. 117/89

(57) ABSTRACT

A method for the production of an InP single crystal includes gradually cooling a molten raw material held in contact with a seed crystal to solidify the molten raw material from a lower part toward an upper part of an interior of a crucible and grow a single crystal, causing the seed crystal to possess an average dislocation density of less than 10000/cm² and assume substantially identical cross-sectional shape and size with a cross-sectional shape and size of a single crystal to be grown, and allowing the InP single crystal to be grown to retain a non-doped state or a state doped with Fe or Sn.

### CROSS REFERENCE TO RELATED APPLICATIONS:

This application is an application filed under 35 U.S.C. § 111(a) claiming the benefit pursuant to 35 U.S.C. § 119(e)(1) of the filing date of Provisional Application No. 60/489,494 filed Jul. 24, 2003 pursuant to 35 U.S.C. § 111(b).

### TECHNICAL FIELD:

This invention relates to a method for the production of an indium phosphide (InP) and a gallium arsenide (GaAs) compound semiconductor single crystals of low dislocation density by the vertical gradient freezing technique (hereinafter referred to as “VGF technique”) or the vertical Bridgman technique (hereinafter referred to as “VB technique”).

### BACKGROUND ART:

As a method for the production of a GaAs single crystal and an InP single crystal, the liquid encapsulated Czochralski process (hereinafter referred to as “LEC process”) has been generally utilized heretofore. While the LEC process enjoys a strong point of enabling a wafer of a large diameter to be manufactured comparatively easily, it entails a defect of forming a large temperature gradient in the axial direction during the growth of crystal and consequently suffering from a high dislocation density that affects the characteristics and the life of a component.

In contrast, the VGF technique and the VB technique enjoy a strong point of allowing the dislocation density to be easily decreased because they are capable of setting small temperature gradients in the axial direction. Since they execute the growth of crystal in a low temperature gradient, they suffer from a weak point of encountering difficulty in obtaining a single crystal of a low dislocation density with high reproducibility because they tend to induce generation of a twin crystal due to uneven growth caused by a fluctuation of the temperature within the furnace, dislocation propagated from a seed crystal within the crystal in growth, and polycrystallization due to the accumulation of dislocations generated by thermal stress after the growth.

Particularly in the case of the growth of an InP crystal by the VGF technique or the VB technique, since the stacking fault energy thereof which bears on the generation of a twin crystal is smaller than that of the GaAs crystal, this growth of the crystal entails the problem of easily generating a twin crystal and extremely degrading the yield of a single crystal. Regarding this matter, the success attained by the use of a seed crystal substantially identical in cross-sectional shape and size with a target crystal in obviating the necessity for making a complicate control of crystal growth relative to a diameter-increased part, simplifying the structure of a crucible, diminishing the loss of crystal liable to occur in the diameter-increased part, realizing a decrease of the dislocation density and enabling a single crystal to be obtained in high yield has been reported (for example, in (JP-A HEI 3-40987), (Advanced Electronics Series 1-4, “Technology of Bulk Crystal Growth,” compiled and written by Keigo Hoshikawa, published by Baifukan, p. 239) and (U. Sahr, et al: 2001 International Conference on Indium Phosphide and Related Materials: “Growth of S-doped 2” InP-Crystals by the Vertical Gradient Freeze Technique, pp 533-536)).

When a crystal grown by the ordinary LEC process is used as a non-doped seed crystal having a dislocation density on the order of 70000/cm², the growth of this non-doped crystal enables the crystal of the grown part to acquire an average dislocation density of 7000/cm², i.e. a decrease to the order of 1/10 or less of the original level, and nevertheless entails the problem that this decrease fails to reach the target level of 5000/cm² or less.

Consequently, the Fe-doped InP crystals intended for high-speed electronic devices that are used in popular high-frequency devices and the Sn-doped InP crystals intended mainly for light-receiving devices have dislocation densities of similar degrees. It is difficult for them to lower their average dislocation densities to below the target level of 5000/cm² or less.

As regards the S-doped InP crystals, Zn-doped InP crystals and the Si-doped or Zn-doped GaAs crystals which are used in the laser devices, the wafers formed of these crystals are required to possess extremely low dislocation densities because the dislocations in the wafers have a great effect to bear on the lives of the laser devices.

These wafers are required to have a low dislocation density of less than 500/cm² in most of the regions thereof When the non-doped crystal grown by the ordinary LEC process is used as a seed crystal, the average dislocation density can be lowered to about 1000/cm² owing to the hardening action of such impurities of S element, Zn element or Si element incorporated as a dopant. It is, however, difficult for this crystal to lower the average dislocation density thereof to the target level of less than 500/cm² throughout the entire region of a wafer.

In the production of the GaAs single crystal, the VGF technique or VG technique that obtains the single crystal of a diameter aimed at by forming an increased-diameter part while pulling a thin seed crystal is generally employed. This technique indeed obtains the single crystal having an average dislocation density aimed at but entails the problem of producing the single crystal only in a low yield. This low yield of the growth of this single crystal is ascribed to the fact that since the use of the slender seed crystal requires the seed crystal to grow via the increased diameter part to the straight barrel part while varying the diameter thereof accordingly, even a slight fluctuation of the temperature inside the furnace brings an influence of exalting the probability of generation of a twin crystal and generation of a polycrystal.

This invention has been initiated with a view to solving the problem mentioned above. It is aimed at providing a method which is capable of producing a single crystal of a high grade of average dislocation density with the object of affording InP single crystals intended for high-speed electronic devices for use in high-frequency devices, InP single crystals intended for light-receiving devices, or InP single crystals or GaAs single crystals intended for laser devices and providing a single crystal possessing an average dislocation density aimed at.

### DISCLOSURE OF THE INVENTION:

This invention provides a method for the production of an InP single crystal comprising gradually cooling a molten raw material held in contact with a seed crystal to solidify the molten raw material from a lower part toward an upper part of an interior of a crucible and consequently grow a single crystal, causing the seed crystal to possess an average dislocation density of less than 10000/cm² and assume substantially identical cross-sectional shape and size with a cross-sectional shape and size of a single crystal to be grown and allowing the InP single crystal to be grown to retain a non-doped state or a state doped with Fe or Sn.

In the method, the seed crystal embraces a seed crystal that possesses a largest dislocation density of less than 30000/cm².

In the method, the seed crystal embraces a seed crystal that has been manufactured from an InP single crystal produced by the method.

This invention also provides a non-doped, Fe-doped or Sn-doped InP single crystal possessing a dislocation density of less than 5000/cm² and produced by the aforementioned method.

This invention further provides a production method for the production of an InP single crystal comprising gradually cooling a molten raw material held in contact with a seed crystal to solidify the molten raw material from a lower part toward an upper part of an interior of a crucible and consequently grow a single crystal, causing the seed crystal to possess an average dislocation density of less than 500/cm² and assume substantially identical cross-sectional shape and size with a cross-sectional shape and size of a single crystal to be grown and allowing the InP single crystal to be grown to retain a state doped with S or Zn.

In the production method, the seed crystal embraces a seed crystal that possesses a largest dislocation density of less than 3000/cm².

In the production method, the seed crystal embraces a seed crystal that has been manufactured from an InP single crystal produced by the production method.

This invention further provides an S-doped or Zn-doped InP single crystal that possesses a dislocation density of less than 500/cm² and is produced by the production method.

This invention also provides a method for the production of a GaAs single crystal comprising gradually cooling a molten raw material held in contact with a seed crystal to solidify the molten raw material from a lower part toward an upper part of an interior of a crucible and consequently grow a single crystal, causing the seed crystal to possess an average dislocation density of less than 500/cm² and assume substantially identical cross-sectional shape and size with a cross-sectional shape and size of a single crystal to be grown and allowing the GaAs single crystal to be grown to retain a state doped with Si or Zn.

In the method just mentioned above, the seed crystal embraces a seed crystal that possesses a largest dislocation density of less than 3000/cm².

In the method, the seed crystal embraces a seed crystal that has been manufactured from a GaAs single crystal produced by the method.

This invention further provides a Si-doped or Zn-doped GaAs single crystal possessing a dislocation density of less than 500/cm² and produced by the method.

This invention, in the growth of an InP single crystal as described above, results in growing a single crystal having an average dislocation density of 2000/cm² using a seed crystal having an average dislocation density of less than 10000/cm² or results in growing a single crystal having an average dislocation density of 500/cm² using a seed crystal having an average dislocation density of less than 500/cm².

The method of this invention can produce a single crystal of a high grade of average dislocation density aimed at as described above. The single crystals that are produced by the method of this invention, therefore, are used in high-speed electronic devices of high-frequency devices, light-receiving devices and laser devices.

### BRIEF DESCRIPTION OF THE DRAWING:

FIG. 1 is a schematic cross section of a crystal growth furnace that is used when this invention is applied to the VGF technique.

FIG. 2 is a schematic cross section of a seed crystal and a crucible used in an experiment of Comparative Example 3.

### BEST MODE FOR CARRYING OUT THE INVENTION

This invention concerns a method for producing a single crystal by gradually cooling a molten raw material held in contact with a seed crystal, thereby solidifying the molten raw material successively from the lower part toward the higher part of the interior of a crucible and attaining growth of the single crystal and requires the seed crystal to be used to assume substantially identical cross-sectional shape and size with the cross-sectional shape and size of a single crystal to be grown and possess an average dislocation density of less than 10000/cm² and preferably possess the largest dislocation density of less than 30000/cm².

As a result, a single crystal having the average dislocation density decreased to 1000/cm², i.e. a level about 1/10 of the original level, is grown.

For the sake of growing a single crystal having an extremely low dislocation density, it is proper to use a seed crystal that has an average dislocation density of less than 500/cm² and the largest dislocation density of less than 3000/cm².

By using a seed crystal of this grade which is not doped or which is doped with the same dopant as used in the crystal to be grown, a S-doped or Zn-doped InP single crystal or a Si-doped or Zn-doped GaAs single crystal is grown.

As a result, a single crystal having an average dislocation density of 500/cm² and befitting a laser device is grown so as to allow production of compound semiconductors of high quality inducing no twin crystal in a high yield.

Now, the embodiment of executing the growth of an InP crystal according to this invention will be described below.

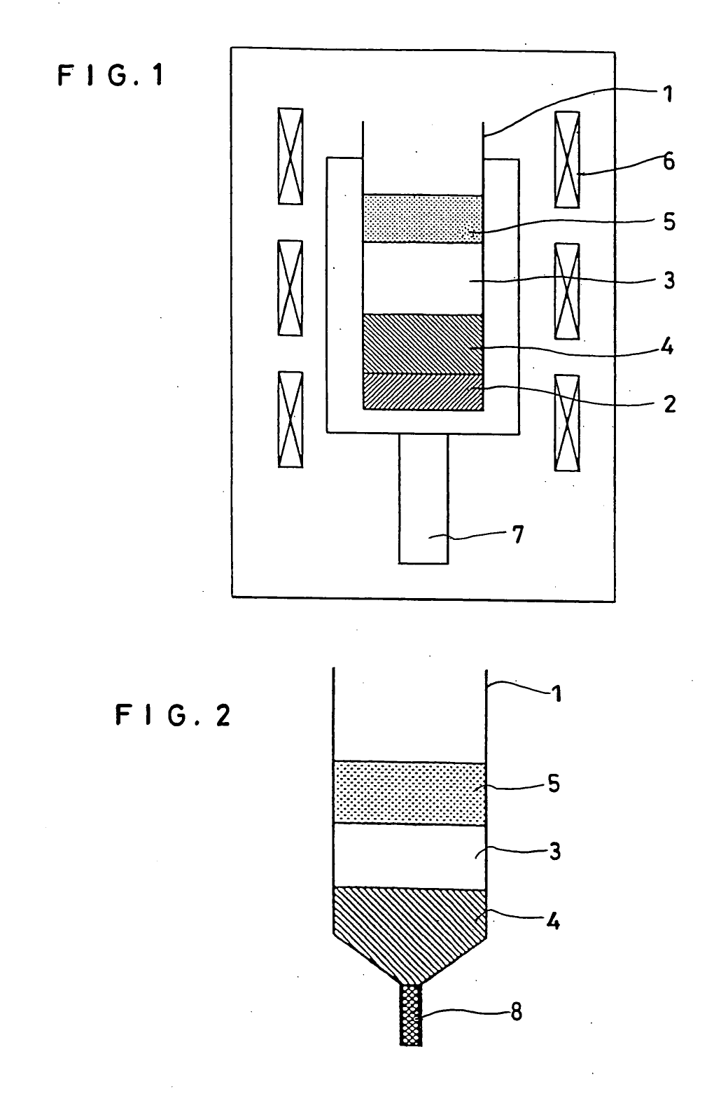

FIG. 1 is a schematic cross section of a crystal growth furnace to be used in the application of this invention to the VGF technique. With reference to FIG. 1, a seed crystal 2 assuming substantially identical cross-sectional shape and size with the cross-sectional shape and size of a crystal to be grown and possessing a low dislocation density is set in place on the bottom part of a crucible made of PBN. A solid grown crystal 4 overlies the seed crystal 2, and a molten raw material 3 not yet crystallized overlies the crystal 4. The upper side of the molten raw material 3 is covered with a liquid sealant 5 (B₂O₃) for preventing vaporization of phosphorus from the molten raw material. The crucible 1 is provided on the peripheral surface thereof with a heater 6 which is adapted to keep the molten raw material 3 and the sealant 5 intact and form a temperature distribution such that the temperature will be retained on the seed crystal 2 side of the interior of the furnace at a low level for allowing the crystal to grow and will be heightened toward the upper part of the interior. A susceptor 7 serves the purpose of supporting the crucible.

These growth jigs are disposed inside a high-pressure vessel and the furnace has the interior thereof filled with an atmosphere of inert gas. The growth of a crystal is made by lowering the controlling temperature of the heater to thereby solidify the molten raw material from the seed crystal side upwardly. In the VB technique, the solidification is accomplished by relatively moving the heater and the crucible.

The seed crystal to be used properly possesses an average dislocation density of less than 10000/cm² and preferably the largest dislocation density of less than 30000/cm² as well. By using this seed crystal, a non-doped, Fe-doped or Sn-doped InP single crystal is grown. The seed crystal to be used for growing a crystal of an extremely low dislocation density properly possesses an average dislocation density of less than 500/cm² or the largest dislocation density of less than 3000/cm². By using a seed crystal having this grade of quality, a S-doped or Zn-doped InP single crystal or a Si-doped or Zn-doped GaAs single crystal is grown.

In the manufacture of a seed crystal having such a low dislocation density, the crystal that is manufactured by the ordinary LEC process cannot be easily used as the seed crystal because it imparts no sufficient decrease of dislocation density to the crystal to be grown. The present invention uses as the seed crystal the crystal of a low dislocation density that is grown by the modified LEC process capable of attaining the growth in a low temperature gradient under a controlled atmosphere of a Group V element or by the horizontal boat technique instead of the LEC process. It goes without saying that the crystal of a low dislocation density which has been grown by the VGF or VG technique according to the method of this invention can be used as the raw material for a seed crystal.

The method for determining the average dislocation density in a given crystal consists in measuring average dislocation densities at intervals of 5 mm in the radial direction within the surface of a given wafer and averaging the numerical values consequently obtained. The largest dislocation density of this crystal is determined by dividing the entire surface of the wafer into squares of 5 mm, measuring a dislocation density at one point in each of the squares of 5 mm, preparing an in-plane distribution of dislocation densities and finding the largest of numerical values shown in the in-plane distribution.

As the seed crystal, the non-doped crystal that has incorporated no element of any sort as a dopant therein can be generally used. The crystal that has been doped with the element that is same as the crystal to be grown can be also used. It is permissible to utilize the seed crystal repeatedly.

Now, concrete Examples of this invention will be described below. This invention does not need to be limited to the following Examples.

### EXAMPLE 1

As a device for growing a crystal, a VGF furnace illustrated in FIG. 1 was used.

First, a crucible made of PBN and measuring 52 mm in inside diameter was charged with a seed crystal measuring 51.5 mm in diameter and 20 mm in thickness, 1000 g of an InP polycrystal raw material and 200 g of B₂O₃ and accommodated in a susceptor. The seed crystal was not grown by the ordinary LEC process but was grown by the modified LEC process using an atmosphere of phosphorus. This seed crystal possessed an average dislocation density of 8200/cm² and a largest dislocation density of 27000/cm². The susceptor vessel packed with the seed crystal, polycrystal raw material and B₂O₅ was disposed in the furnace. The furnace was then made to introduce argon gas as an inert gas till the interior pressure thereof reached 40 atmospheres (4 MPa). The heater was operated to heat the interior of the furnace to a temperature of about 1070° C. so as to melt the B₂O₅ and the polycrystal raw material. After the thorough melting of the polycrystal raw material was confirmed, the temperature of the seed crystal part was made to equal the melting point of InP (1062° C.) and the heater temperature was lowered in order for the crystal growth speed to reach 2 mm/hr. The crystal was grown for about 50 hours and the hot crystal was cooled to room temperature over a period of 10 hours.

After the grown crystal was cooled to room temperature, the furnace was opened to extract the crucible. The B₂O₃ in the PBN crucible was dissolved in alcohol so as to induce removal of the non-doped InP crystal. The crystal consequently obtained was an InP single crystal measuring 2 inches in diameter and 90 mm in total length and generating absolutely no twin crystal. When the single crystal ingot was cut and examined to determine dislocation density, it was found to be a single crystal having such a low average dislocation density of 1240/cm².

When five experiments were carried out on the growth of a non-doped InP single crystal by using a seed crystal having an average dislocation density of less than 10000/cm², the five experiments invariably avoided forming a twin crystal and obtained single crystals having lower dislocation densities than 2000/cm². Thus, they demonstrated successful production of an InP single crystal of low dislocation density with high reproducibility.

When a non-doped InP single crystal was grown by using as a new seed crystal the aforementioned grown part possessing an average dislocation density of 1240/cm², the single crystal ingot consequently obtained possessed a further lowered average dislocation density than in the previous growth of crystal, and the single crystal obtained from the ingot possessed an average dislocation density of 480/cm². The experiment has demonstrated that the use of a crystal having a low dislocation density as a seed crystal permits the growth of a single crystal possessing a further lower dislocation density.

While Example 1 has demonstrated the growth of a non-doped InP crystal, the growth of a Fe-doped InP crystal that is used in high-frequency electronic devices and the growth of an Sn-doped crystal that is used as the substrate for a-light-receiving device can be accomplished in the same manner as in Example 1.

### EXAMPLE 2

Example 2 demonstrates the growth of a S-doped InP crystal. While a non-doped single crystal that has incorporated no impurity of any sort therein is generally used as a seed crystal, it is permissible to use a crystal that has been doped with the same impurity as the crystal to be grown.

In this Example 2, a S-doped crystal grown by the VGF technique was used as a seed crystal. This seed crystal measured 51.5 mm in diameter and 20 mm in thickness and possessed an average dislocation density of 420/cm². The crystal, during the growth thereof, incorporated In₂S₃ as a dopant therein, with the incorporation so controlled as to adjust the carrier concentration in the growth initiating part at 1×10¹⁸/cm³. The other conditions for the growth of the crystal herein were the same as in Example 1. The crystal consequently obtained was an InP single crystal measuring 2 inches in diameter and 90 mm in total length and forming absolutely no twin crystal. When the single crystal ingot was cut to determine dislocation density, it was found to possess an average dislocation density of 80/cm² and the largest dislocation density of 1000/cm². Not less than 95% of the 5 mm squares within the surface of the wafer possessed dislocation densities of less than 500/cm².

### EXAMPLE 3

Example 3 demonstrated the growth of a Si-doped GaAs crystal.

The seed crystal used herein was a Si-doped GaAs crystal grown by the VGF technique. This seed crystal measured 51.5 mm in diameter and 20 mm in thickness and possessed an average dislocation density of 400/cm². A crucible made of PBN and measuring 52 mm in inside diameter was used and charged with 1000 g of a polycrystal raw material for GaAs and 200 g of B₂O₃. The crystal, during the growth thereof, incorporated Si as a dopant therein, with the incorporation so controlled as to adjust the carrier concentration in the growth initiating part at 7×10¹⁷/cm³. The crystal consequently obtained was a GaAs single crystal measuring 2 inches in diameter and 80 mm in total length and forming absolutely no twin crystal. When the single crystal ingot was cut to determine dislocation density, it was found to possess an average dislocation density of 120/cm² and the largest dislocation density of 1000/cm². As much as 96% of the 5 mm squares within the surface of the wafer possessed dislocation densities of less than 500/cm².

### COMPARATIVE EXAMPLE 1

By following the procedure of Example 1, the growth of an InP crystal was carried out while using a non-doped InP single crystal manufactured by the ordinary LEC process and possessing an average dislocation density of 80000/cm² as a seed crystal instead. The non-doped crystal consequently obtained was a single crystal in which the growth initiating part possessed a dislocation density lowered to 7000/cm² and the trailing part of crystal revealed the presence of a polycrystal. When five experiments were carried out on the growth of an InP crystal under the same conditions, the absence of a polycrystal in the entire region from the growth initiating part through the growth terminating part was confirmed in only two of the single crystals obtained and the presence of a polycrystal in the trailing part of crystal was confirmed in the other three single crystals.

### COMPARATIVE EXAMPLE 2

By following the procedure of Example, 2 the growth of an InP crystal was carried out while using as a seed crystal a non-doped InP crystal manufactured by the VGF technique and possessing an average dislocation density of 8000/cm². The S-doped crystal consequently obtained was a single crystal throughout the entire region thereof and it possessed an average dislocation density of 840/cm² on the seed side and 520/cm² on the tail side. It thus failed to acquire a sufficient decrease in dislocation density as evinced by not satisfying the requirement that an S-doped InP crystal for use in a laser device be possessed of an average dislocation density of less than 500/cm².

### COMPARATIVE EXAMPLE 3

Comparative Example 3 demonstrated the growth of a Si-doped GaAs crystal. The seed crystal used herein was a Si-doped GaAs single crystal measuring 8 mm in diameter, i.e. a greater slenderness than in Examples cited above, and possessing an average dislocation density of 400/cm². A crucible made of PBN and including a diameter-increased part was used herein. The appearance of this crucible and a seed crystal disposed therein is depicted in FIG. 2. The other conditions of the crucible were the same as those of Example 3. By following the procedure of Example 3, the growth of a crystal was carried out while operating the crucible as described above instead. The crystal consequently obtained was a GaAs single crystal measuring 2 inches in diameter and 80 mm in total length. When the single crystal ingot was cut to determine dislocation density, it was found to possess an average dislocation density decreased to 80/cm². When five experiments were carried out on the growth of a GaAs crystal under the same conditions, the absence of a twin crystal in the entire region of crystal was confirmed in only two of the single crystals obtained. In the other three single crystals, a twin crystal occurred in the entire region of crystal to the extent of lowering the yield of a single crystal.

### INDUSTRIAL APPLICABILITY:

The VGF technique or the VG technique according to this invention allows a single crystal of an extremely low dislocation density to be produced with a very small loss by the use of a small crucible simple in construction. Particularly, the InP single crystal and the GaAs single crystal that are obtained by the method are single crystals of low dislocation density and, therefore, are suitable as materials for electronic devices, such as high-frequency devices, high-speed electronic devices, laser devices and light-receiving devices.

1. A method for the production of an InP single crystal, comprising:
gradually cooling a molten raw material held in contact with a seed crystal to solidify the molten raw material from a lower part toward an upper part of an interior of a crucible and grow a single crystal;
causing the seed crystal to possess an average dislocation density of less than 10000/cm² and assume substantially identical cross-sectional shape and size with a cross-sectional shape and size of a single crystal to be grown; and
allowing the InP single crystal to be grown to retain a non-doped state or a state doped with Fe or Sn.

2. A method according to claim 1, wherein the seed crystal is a seed crystal possessing a largest dislocation density of less than 30000/cm².

3. : A method according to claim 1, wherein the seed crystal is a seed crystal manufactured from an InP single crystal produced by the method according to claim 1.

4. A method for the production of an InP single crystal, comprising:
gradually cooling a molten raw material held in contact with a seed crystal to solidify the molten raw material from a lower part toward an upper part of an interior of a crucible and consequently grow a single crystal;
causing the seed crystal to possess an average dislocation density of less than 500/cm² and assume substantially identical cross-sectional shape and size with a cross-sectional shape and size of a single crystal to be grown; and
allowing the InP single crystal to be grown to retain a state doped with S or Zn.

5. A method according to claim 4, wherein the seed crystal is a seed crystal possessing a largest dislocation density of less than 3000/cm².

6. A method according to claim 4, wherein the seed crystal is a seed crystal manufactured from an InP single crystal produced by the method according to claim 4.

7. A method for the production of a GaAs single crystal, comprising:
gradually cooling a molten raw material held in contact with a seed crystal to solidify the molten raw material from a lower part toward an upper part of an interior of a crucible and consequently grow a single crystal;
causing the seed crystal to possess an average dislocation density of less than 500/cm² and assume substantially identical cross-sectional shape and size with a cross-sectional shape and size of a single crystal to be grown; and
allowing the GaAs single crystal to be grown to retain a state doped with Si or Zn.

8. A method according to claim 7, wherein the seed crystal is a seed crystal possessing a largest dislocation density of less than 3000/cm².

9. A method according to claim 7, wherein the seed crystal is a seed crystal manufactured from a GaAs single crystal produced by the method according to claim 7.

10. A non-doped, Fe-doped or Sn-doped InP single crystal possessing a dislocation density of less than 5000/cm², which is manufactured by the method according to claim 1.

11. A non-doped, Fe-doped or Sn-doped InP single crystal possessing a dislocation density of less than 5000/cm², which is manufactured by the method according to claim 3.

12. An S-doped or Zn-doped InP single crystal possessing a dislocation density of less than 500/cm², which is manufactured by the method according to claim 4.

13. An S-doped or Zn-doped InP single crystal possessing a dislocation density of less than 500/cm², which is manufactured by the method according to claim 6.

14. An Si-doped or Zn-doped GaAs single crystal possessing a dislocation density of less than 500/cm², which is manufactured by the method according to claim 7.

15. An Si-doped or Zn-doped GaAs single crystal possessing a dislocation density of less than 500/cm², which is manufactured by the method according to claim 9.
